(19) United States
(12) Patent Application Publication
(10) Pub. No.: US 2015/0187892 A1
(43) Pub. Date: Jul. 2, 2015

(54) METHOD FOR MANUFACTURING SEMICONDUCTOR DEVICE

(71) Applicant: Institute of Microelectronics, Chinese Academy of Sciences, Beijing (CN)

(72) Inventors: Haizhou Yin, Poughkeepsie, NY (US); Keke Zhang, Liaocheng City (CN)

(21) Appl. No.: 14/416,698

(22) PCT Filed: Aug. 3, 2012
(86) PCT No.: PCT/CN2012/079694

§ 371 Date: Jan. 23, 2015

(30) Foreign Application Priority Data
Jul. 24, 2012 (CN) 201210258807.6

(51) Int. Cl. H01L 29/40; H01L 29/06; H01L 29/66

(52) U.S. Cl. CPC H01L 29/401; H01L 29/665; H01L 29/6653; H01L 29/0649

(57) ABSTRACT

A method for manufacturing a semiconductor device is disclosed, comprising: forming a contact sacrificial layer on the substrate, etching the contact sacrificial layer to form a contact sacrificial pattern, wherein the contact sacrificial pattern covers the source region and the drain region and has a gate trench that exposes the substrate; forming a gate spacer and a gate stack structure in the gate trench; partially or completely etching off the contact sacrificial pattern that covers the source region and the drain region so as to form a source/drain contact trench; and forming a source/drain contact in the source/drain contact trench. By means of the double-layer contact sacrificial layer, the method for manufacturing a semiconductor device in accordance with the present invention effectively reduces the spacing between the gate spacer and the contact region and increases the area of contact region, thus effectively reducing the parasitic resistance of the device.

This application claims the benefits of prior Chinese Patent Application No. 201210258807.6 filed on Jul. 24, 2012, titled “method for manufacturing a semiconductor device”, which is incorporated herein by reference in its entirety.

### TECHNICAL FIELD

The present invention relates to the field of manufacturing semiconductor integrated circuits. In particular, the present invention relates to a method of manufacturing a MOSFET having an increased contact region.

### BACKGROUND ART

As the feature size of MOSFET are scaled continuously, the proportion of parasitic resistance in the total resistance of the device is growing, which seriously restricts the enhancement of properties of small size devices. The existing structure/method to reduce parasitic resistance comprises forming raised source/drain, forming a metal silicide in/on the source/drain region, increasing contact area, and so on.

However, no matter which structure/method is used, there is still a large distance between the contact area (or contact aperture, CA) and the gate spacer, and the distance of carriers of electrons/holes traveling from the source region to the drain region through the channel region is still large. Thus, parasitic resistance still cannot be effectively reduced and the enhancement of the device performance is limited.

### SUMMARY OF THE INVENTION

In view of the above, one aspect of the present invention is to provide a new manufacturing method of a contact sacrificial layer process to substitute for the traditional replacement gate process, and to reduce the distance between the contact region and the gate significantly, thereby effectively reducing the parasitic resistance of the device.

The above aspect of the present invention is achieved by providing a method for manufacturing a semiconductor, comprising: forming a contact sacrificial layer on a substrate, etching the contact sacrificial layer to form a contact sacrificial pattern, wherein the contact sacrificial layer covers source and drain regions and has a gate trench that exposes the substrate; forming a gate spacer and a gate stack structure in the gate trench; partially or completely etching off the contact sacrificial pattern that covers the source region and the drain region so as to form a source/drain contact trench; and forming a source/drain contact in the source/drain contact trench.

The contact sacrificial layer includes a first contact sacrificial layer and a second contact sacrificial layer.

The first contact sacrificial layer includes strained Si, SiGe, Si:C, polycrystalline silicon, amorphous silicon, microcrystalline silicon, amorphous carbon, silicon oxide, silicon nitride, or any combination thereof; and the second contact sacrificial layer includes single crystal silicon, polycrystalline silicon, amorphous silicon, microcrystalline silicon, amorphous carbon, silicon oxide, silicon nitride, or any combination thereof

The step of forming a source/drain contact trench comprises: partially etching off the sacrificial; or completely etching off the second contact sacrificial layer and partially etching off the first contact sacrificial layer; or completely etching off the second contact sacrificial layer and the first contact sacrificial layer; or completely etching off the second contact sacrificial layer and the first contact sacrificial layer and partially etching the substrate.

A contact sacrificial layer is formed by epitaxial growth and is doped to have a first conductivity type.

After a contact sacrificial layer is formed, the contact sacrificial layer and the substrate are etched to form a shallow trench, and the shallow trench is filled with an insulating material to form a shallow trench isolation.

After a gate trench is formed, the shallow trench isolation is etched such that it is tilted towards the isolation region in the width direction of the active region.

After a contact sacrificial pattern is formed, a lightly-doped source/drain region is provided in the substrate on both sides of the gate trench.

The formation of a gate stack structure comprises depositing a gate insulating layer of a high-k material, a work function adjustment layer of a metal nitride, and a resistance adjustment layer of a metal in the gate trench.

The step of forming a source/drain contact further comprises: forming a metal silicide in the source/drain contact trench; depositing a liner and a filling layer sequentially on the metal silicide; and planarizing the filling layer and the liner until the gate stack structure is exposed.

By means of a double-layer contact sacrificial layer process, the method for manufacturing a semiconductor device according to the present invention effectively reduces the spacing between the gate spacer and the contact region and increases the area of contact region, thus effectively reducing the parasitic resistance of the device.

### BRIEF DESCRIPTION OF THE FIGURES

The technical solutions of the present invention are described in detail with reference to the drawings, wherein:

FIGS. 1 to 9 are cross-sectional views showing the steps of a method for manufacturing a semiconductor device according to the present invention; and

FIG. 10 is a flowchart of a method for manufacturing a semiconductor device according to the present invention.

### DESCRIPTION OF THE PREFERRED EMBODIMENTS

The characteristics and technical effects of the technical solution of the present invention is described in detail referring to the figures in combination with schematic embodiments. What should be noted is that: similar reference signs denote similar structures, and the terms “first”, “second”, “above”, “below”, “thick”, “thin”, and so on used in the present application can be used for modifying various device structures. These modifications, unless otherwise stated, do not imply the space, order, or hierarchical relationship of the device structure modified.

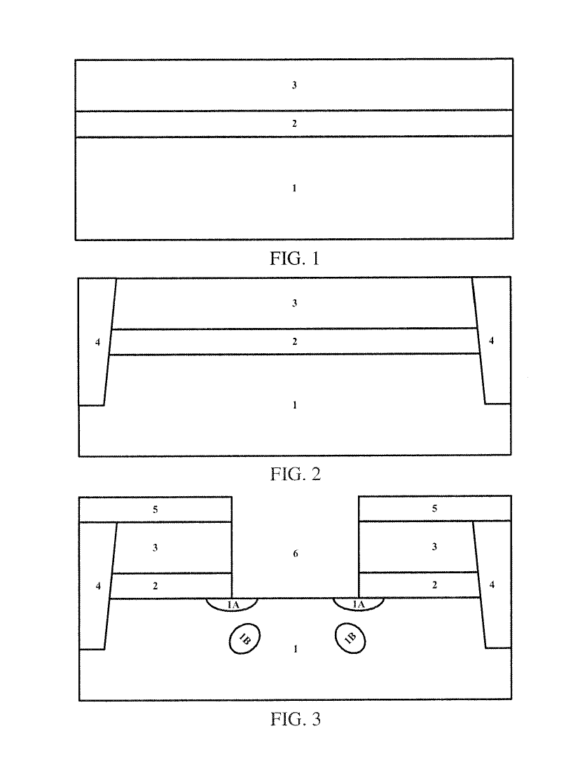

Referring to FIG. 10 and FIGS. 1 to 4, a contact sacrificial pattern is formed on the substrate, covering the source region and the drain region and exposing the gate region.

As shown in FIG. 1, a first contact sacrificial layer and a second sacrificial layer are sequentially formed on a substrate 1. The substrate 1 is provided, which may be of (bulk) Si (for example, single-crystal Si wafer), SOI, single-crystal Ge, GeOI (Ge on an insulator), or any other compound semiconductor such as GaAs, SiGe, GeSn, InP, InSb, and GaN. Preferably, the substrate 1 may be bulk Si or SOI so as to be compatible with the CMOS process.

By using a conventional method such as LPCVD, PECVD, HDPCVD, MOCVD, MBE, ALD, evaporation, and sputtering and properly controlling the process parameters, a first contact sacrificial layer 2 is epitaxially grown on the substrate 1. The first contact sacrificial layer 2 is used for the actual source/drain region (as a portion of the raised source/drain) of the device to be formed, the material of which may be strained Si, SiGe, Si:C, or any combination thereof, and the thickness of which may be, for example, 10 to 100 nm. Since the lattice constant of the material of the first contact sacrificial layer 2 and that of the material of the substrate 1 are different, stress can be applied to the channel region, thereby improving the carrier mobility and enhancing the driving capability of the device. Preferably, by epitaxial growth and simultaneously in-situ doping or an additional ion implantation process after epitaxial growth, the first contact sacrificial layer 2 has a first conductivity type, e.g., n or p type. Furthermore, the first contact sacrificial layer 2 can also be polycrystalline silicon, amorphous silicon, microcrystalline silicon, amorphous carbon, silicon oxide, or silicon nitride, etc. At this time, the first contact sacrificial layer 2 will be completely removed in the subsequent process of forming a source/drain contact trench as shown in FIG. 7.

Subsequently, by a similar epitaxial process, a second contact sacrificial layer 3 is further epitaxially formed on the first sacrificial layer 2 for defining the region for forming a source/drain contact later, which plays a similar function to the dummy-gate in the gate-last process and therefore is also referred to as a dummy source/drain contact region. The material of the second contact sacrificial layer 3 can be the same as the substrate 1, e.g., Si (which may be single crystal silicon, or polycrystalline silicon, amorphous silicon, microcrystalline silicon; in this case, the second contact sacrificial layer 3 is not completely removed by etching in the subsequent process but part of it is retained to be used as a portion of the raised source/drain region). Alternatively, the material of the second contact sacrificial layer 3 can be different from that of the substrate 1, which may be, for example, amorphous carbon, silicon nitride, silicon oxide, or silicon nitride oxide (in this case, the second contact sacrificial layer 3 will be completely removed by etching in the subsequent process until the first contact sacrificial layer 2 is exposed). The second contact sacrificial layer 3 has a thickness greater than that of the first contact sacrificial layer 2, preferably 40 to 500 nm. The sum of the thickness of the first contact sacrificial layer 2 and the second sacrificial layer 3 is greater than the height of the gate to be formed later, for example, 50 to 500 nm. Preferably, when the material of the second contact sacrificial layer 3 includes Si (i.e., when a part would be retained to be used as a portion of the raised source/drain region), by epitaxial growth and simultaneously in-situ doping or an additional ion implantation process after epitaxial growth, the second contact sacrificial layer 3 also has a first conductivity type with higher concentration, e.g., n+ or p+.

As shown in FIG. 2, a shallow trench isolation (STI) 4 is formed. Traditional photolithography/etching techniques are used to etch through the second contact sacrificial layer 3 and the first contact sacrificial layer 2 sequentially, and to partially etch the substrate 1 so as to form a shallow trench (not shown). By a method such as PECVD, HDPCVD, RTO (rapid thermal oxidation), MBE and ALD, an insulating film of a silicon oxide or silicon nitride oxide material is deposited in the shallow trench so as to form a shallow trench isolation (STI) 4. Further preferably, the isolation oxide with which the STI 4 is filled can also be a large thermal expansion dielectric material having an absolute value of linear volume expansion coefficient of greater than 10⁻⁴/K at a temperature of 100K, for example, perovskite type oxides including Bi_{0.95}La_{0.05}NiO₃, BiNiO₃, ZrW₂O₈ and the like, or framework materials such as Ag₃[Co(CN)₆]. These large thermal expansion dielectric materials can apply stress to an active region, to further increase the carrier mobility and enhance the device performance. The cross-sectional shape of the STI 4 is not limited to a trapezoid with a top edge wider than the bottom edge as shown in FIG. 2, and can also be a rectangle with a top edge equal to the bottom edge, or a trapezoid with a top edge narrower than the bottom edge (to increase the stress of the lower part of the active region).

As shown in FIG. 3, the second contact sacrificial layer 3 and the first contact sacrificial layer 2 are etched and the gate region is exposed via a gate trench 6 to form a contact sacrificial pattern. The photoresist layer 5 is spin coated on the entire device, and exposed and developed to form a photoresist pattern, only exposing the region that is to be formed into a gate stack structure. Subsequently, anisotropic etching is used, for example, dry etching such as plasma etching, reactive ion etching, etc., or wet etching such as TMAH (for Si material), a combination of a strong acid (HF) with a strong oxidizing agent (sulfuric acid, hydrogen peroxide) (for SiGe material), etc., to etch the second contact sacrificial layer 3 and the first contact sacrificial layer 2 until the substrate 1 is exposed to form a gate trench 6. The width of the gate trench 6 shall be equal to the sum of the actual width of the gate stack structure (gate insulating layer and gate conductive layer) to be formed later and the width of the gate spacer. The remainder of the second contact sacrificial layer 3 and the first sacrificial layer 2 remains to cover the source region and the drain region of the device to be formed.

Preferably, a source/drain lightly doped process is performed to form a source/drain lightly doped region in the substrate. For example, with a photoresist pattern 5 and the contact sacrificial layer 3/2 below as a mask, angled source/drain ion implantation with a low dose and low energy may be performed, and the implantation position of the dopants may be controled by Shadow Effect so as to form a lightly-doped source/drain extension region 1A, and a Halo source/drain doping region 1B in the substrate below the source/drain extension region. Subsequently, rapid annealing (for example, laser rapid annealing) is performed to activate the dopants. The type, dose and concentration of the implanted ions may be determined in accordance with the requirements of the electrical properties of the device. In addition, optionally, a spacer with a diffusion source may be provided on both sides of the contact sacrificial layer 3/2 in the gate trench 6 to form a lightly-doped source/drain extension region IA by ion diffusion effect, and then the spacer may be removed.

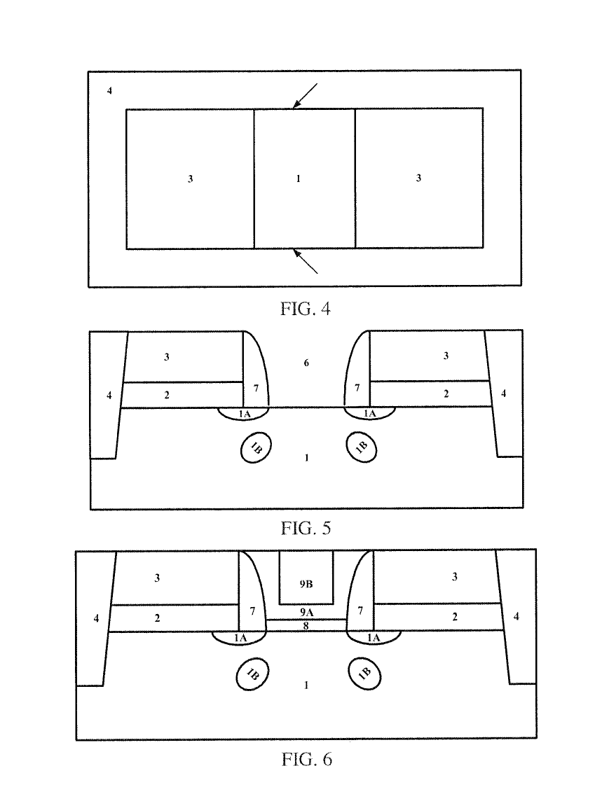

FIG. 4 is a top view after the top photoresist pattern 5 is removed in FIG. 3. An STI etching process is performed so that the part of STI 4 exposed by the side surfaces of the gate trench 6 as shown in FIG. 4 is tilted towards the shallow trench isolation region rather than to the gate trench 6 so as to avoid formation of a gate spacer on the STI 4.

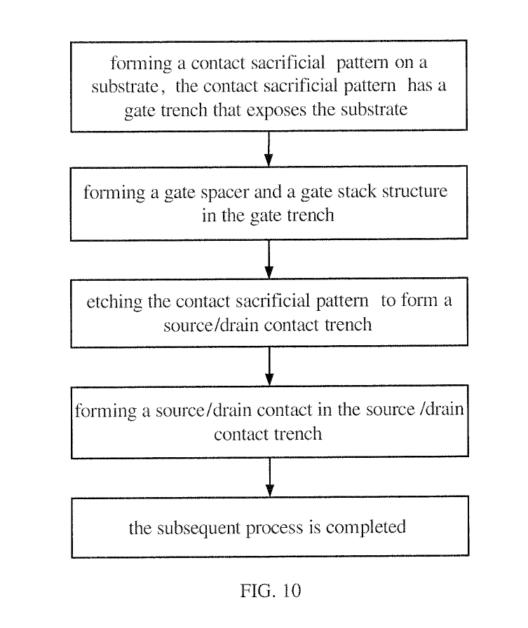

Referring to FIG. 10 and FIG. 5, a gate spacer is formed in the gate trench 6. A Method such as PECVD, HDPCVD, MBE, ALD, and (magnetron) sputtering is used to deposit insulating materials, for example, silicon nitride, silicon oxynitride and amorphous diamond-like carbon (DLC), and then a gate spacer is formed by etching to be located on two side surfaces along the longitudinal direction of the active region (the direction of the channel region) in the gate trench 6 and contacts the first and second sacrificial layers 2/3. Since the STI 4 along the width direction (the extending direction of the device) of the active region in the gate trench 6 is tilted towards the shallow trench isolation region, the insulating materials on the two side surfaces are completely etched off and will not be formed into a gate spacer. The thickness of the gate spacer 7 may be determined in accordance with the requirements of the gate insulating isolation performance, for example, 5 to 30 nm.

Referring to FIG. 10 and FIG. 6, a gate stack structures 8/9 is formed in the gate trench 6. By a method such as PECVD, HDPCVD, MOCVD, MBE, and ALD, a gate insulating layer 8 is deposited on the surface where the bottom of the gate trench 6 contacts the substrate 1. The material of the gate insulating layer 8 is a high-k material including, but not limited to, nitrides (e.g., SiN, AlN, TiN), metal oxides (mainly subgroup and lanthanide metal oxides, for example, Al₂O₃, Ta₂O₅, TiO₂, ZnO, ZrO₂, HfO₂, CeO₂, Y₂O₃, and La₂O₃), perovskite phase oxides (e.g., PbZrₓTi₁₋ₓO₃ (PZT), BaₓSr₁₋ₓTiO₃ (BST)). Subsequently, by a method such as PECVD, MOCVD, MBE, ALD, evaporation, and sputtering, a gate conductive layer 9 is deposited on the second sacrificial layer 3 and the gate trench 6. The gate conductive layer 9 preferably comprises a work function adjusting layer 9A with its material being a metal nitride such as TiN, and TaN, and a resistance adjusting layer 9B with its material being a metal such as Cu, Al, Ti, Mo, Ta, and W. The gate insulating layer 8 and the gate conductive layers 9A/9B together constitute a gate stack structure. Subsequently, an etching-back process or a CMP process is performed to planarize the gate conductive layers 9A/9B until the second contact sacrificial layer 3 is exposed.

Referring to FIG. 10 and FIG. 7, the contact sacrificial pattern is partially or completely removed to form a source/drain contact trench, and a metal suicide is formed in the source/drain contact trench. For example, an anisotropic wet etching solution such as TMAH is employed to remove the second contract sacrificial layer of a silicon-based material such as single crystal silicon, polycrystalline silicon, amorphous silicon, microcrystalline silicon and the like, or oxygen plasma etching is employed to remove the second contact sacrificial layer 3 of an amorphous carbon material. Thus, after the second contact sacrificial 3 is partly (or completely) removed, the source/drain contact trench 3A is left, and the remaining second contact sacrificial layer and gate spacer 7 are exposed. According to one embodiment of the present invention, the depth of the source/drain contact trench 3A as shown in FIG. 7 is less than the original thickness of the second sacrificial layer 3, i.e., only the second sacrificial layer 3 is partially removed (in this case, the remaining part of the second contact sacrificial layer 3 will be used as part of the future source/drain region or one of the source/drain contacts, and therefore its material is preferably a silicon-based material). However, in other embodiments of the present invention, the depth of the source/drain contact trench 3A may be greater than the original thickness of the second sacrificial layer 3. Specifically, the second contact sacrificial layer 3 (not shown, in this case, the second contact sacrificial layer 3 can be of other materials such as amorphous carbon, or can even be of silicon nitride) can be completely removed, and part or all of the first contact sacrificial layer 2 (not shown, in this case, the first contact sacrificial layer 2 will no longer be used as part of the source/drain region, so the material does not have to be SiGe, SiC, etc.) can be further removed by etching, and part of the substrate 1 can even be further removed by etching, wherein the source/drain contact trench 3A is formed to extend into the substrate (in this case, SiGe and SiC can be epitaxially formed in the deep trench and raised source/drain is further formed).

In particular, if the second contact sacrificial layer 3 and the first contact sacrificial layer 2 (or no in-situ doping is performed during the process of epitaxially growing contact sacrificial layers 2/3 and no additional ion injection is performed after epitaxial growth) are completely removed, the substrate exposed in the source/drain contact trench 3A (or the second contact sacrificial layer 3 and/or the first contact sacrificial layer 2) is heavily doped to form a heavily doped region of n+ or p-type as the source/drain heavily doped region.

Thereafter, a metal thin layer (not shown), e.g., Ni, Pt, Co or Ti, or combinations thereof, is formed by sputtering and evaporation in the source/drain contact trench 3A, and then rapid annealing or low temperature annealing (400 to 600° C.) is performed, so that the metal thin layer reacts with Si in the source/drain region to form a metal silicide 10 for further reducing contact resistance. The unreacted metal thin layer is stripped off. In this case, since STI 4 of an oxide material and the gate spacer 7 of a silicon nitride material 7 do not react with the metal thin layer, the metal silicide 10 is only formed in the source/drain region.

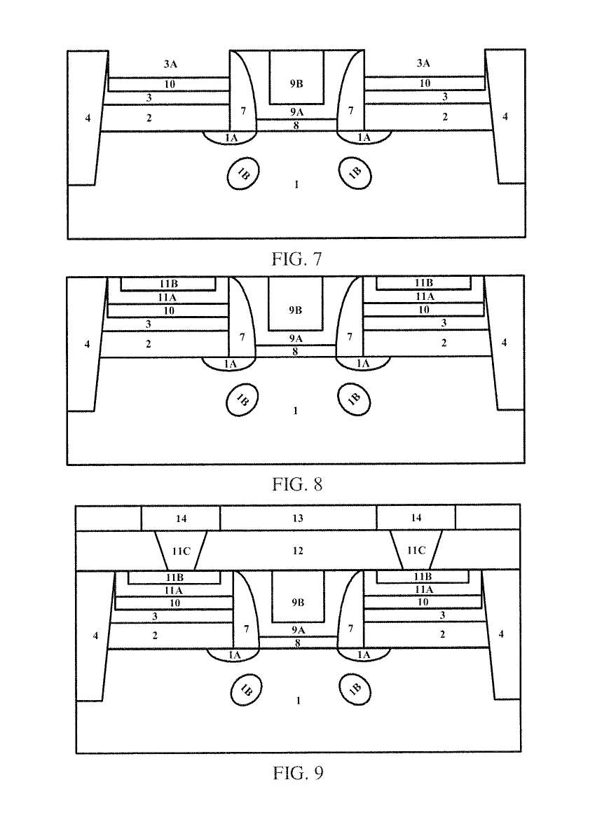

Referring to FIG. 10 and FIG. 8, a barrier layer 11A (a liner) of TiN and TaN materials and a filling layer 11B of W, Al, Mo, and Ti materials are sequentially deposited on the metal silicide 10 in the source/drain contact trench 3A to form a source/drain contact 11. Preferably, a CMP process is employed to planarize the barrier layer 11A/the filling layer 11 B, until the gate conductive layer 9 (resistance adjusting layer 9B) of the gate stack structure is exposed. At this time, the spacing between the source/drain contact 11 and the gate stack structure is only the thickness of the gate spacer 7, i.e., the spacing is substantially reduced; in addition, the source/drain contact 11 covers the entire source/drain region, its area being significantly increased compared to the existing technology. Therefore, the large area source/drain contact in accordance with the present invention effectively reduces parasitic resistance.

Referring to FIG. 10 and FIG. 9, the subsequent process is completed. For example, an interlayer dielectric layer (ILD) 12 of silicon oxide, silicon nitride, and low-k materials is deposited on the entire device. ILD 12 is etched to form a source/drain contact aperture, and the source/drain contact aperture is filled with a metal material to form a second source/drain contact 11C. A second ILD 13 of silicon oxide, silicon nitride, or any other low-k material different from ILD 12 is deposited on the entire device. Interconnected apertures are formed by etching, and a metal such as Al and Ti is deposited in the interconnected apertures to form interconnected lines 14.

By means of a double layer contact sacrificial layer process, the method for manufacturing a semiconductor device according to the present invention effectively reduces the spacing between the gate spacer and the contact region and increases the contact area, thus effectively reducing the parasitic resistance of the device.

Although the present invention is described with reference to one or more exemplary embodiments, those skilled in the art know that a variety of suitable changes and equivalents can be made to the method of forming a device structure without departing from the scope of the present invention. Furthermore, from the teachings disclosed herein, many amendments suitable for specific situations or materials can be made without departing from the scope of the invention. Accordingly, the aspect of the present invention is not limited to particular embodiments used for achieving the best modes to carry out the present invention, while the device structure and its manufacturing method disclosed will include all embodiments that fall within the scope of the invention.

I/We claim:

1. A method for manufacturing a semiconductor device, comprising:
forming a contact sacrificial layer on a substrate, etching the contact sacrificial layer to form a contact sacrificial pattern, wherein the contact sacrificial pattern covers source and drain regions and has a gate trench that exposes the substrate;
forming a gate spacer and a gate stack structure in the gate trench;
partially or completely etching off the contact sacrificial pattern that covers the source and the drain regions so as to form a source/drain contact trench; and
forming a source/drain contact in the source/drain contact trench.

2. The method for manufacturing a semiconductor device of claim 1, wherein the contact sacrificial layer includes a first contact sacrificial layer and a second contact sacrificial layer.

3. The method for manufacturing a semiconductor device of claim 2, wherein the first contact sacrificial layer includes strained Si, SiGe, Si:C, polycrystalline silicon, amorphous silicon, microcrystalline silicon, amorphous carbon, silicon oxide, silicon nitride, or any combination thereof; and the second contact sacrificial layer includes single crystal silicon, polycrystalline silicon, amorphous silicon, microcrystalline silicon, amorphous carbon, silicon oxide, silicon nitride, or any combination thereof.

4. The method for manufacturing a semiconductor device of claim 2, wherein the step of forming a source/drain contact trench comprises: partially etching off the second contact sacrificial layer; or completely etching off the second contact sacrificial layer and partially etching off the first contact sacrificial layer; or completely etching off the second contact sacrificial layer and the first contact sacrificial layer; or completely etching off the second contact sacrificial layer and the first contact sacrificial layer and partially etching the substrate.

5. The method for manufacturing a semiconductor device of claim 1, wherein the contact sacrificial layer is formed by epitaxial growth and is doped to have a first conductivity type.

6. The method for manufacturing a semiconductor device of claim 1, wherein after a contact sacrificial layer is formed, the contact sacrificial layer and the substrate are etched to form a shallow trench, and the shallow trench is filled with an insulating material to form a shallow trench isolation.

7. The method for manufacturing a semiconductor device of claim 6, wherein after the gate trench is formed, the shallow trench isolation is etched so that it is tilted towards an isolation region in a width direction of an active region.

8. The method for manufacturing a semiconductor device of claim 1, wherein after a contact sacrificial pattern is formed, a lightly-doped source/drain region is formed in the substrate on both sides of the gate trench.

9. The method for manufacturing a semiconductor device of claim 1, wherein the formation of a gate stack structure comprises depositing a gate insulating layer of a high-k material, a work function adjustment layer of a metal nitride and a resistance adjustment layer of a metal in the gate trench.

10. The method for manufacturing a semiconductor device of claim 1, wherein the step of forming a source/drain contact further comprises: forming a metal silicide in the source/drain contact trench; depositing a liner and a filling layer sequentially on the metal silicide; and planarizing the filling layer and the liner until the gate stack structure is exposed.
